(19) United States
(12) Patent Application Publication
(10) Pub. No.: US 2024/0186961 A1
(43) Pub. Date: Jun. 6, 2024

(54) LOOP FILTER ASSIST CIRCUIT

(71) Applicant: SKYWORKS SOLUTIONS, INC., Irvine, CA (US)

(72) Inventors: Spencer David Leuenberger, Portland, OR (US); Praveen Kumar Venkatachala, Portland, OR (US); Mark R. Peting, Yamhill, OR (US); David Lamb, Portland, OR (US); Eric Thomas King, San Jose, CA (US); Luigi Panseri, Bedford, MA (US); Calvin Yoji Lee, Corvallis, OR (US)

(21) Appl. No.: 18/515,538

(22) Filed: Nov. 21, 2023

Related U.S. Application Data
(60) Provisional application No. 63/385,925, filed on Dec. 2, 2022.

(51) Int. Cl. H03F 3/04

(52) U.S. Cl. CPC H03F 3/04; H03F 2200/165

(57) ABSTRACT

This disclosure relates generally to a system for mitigating error in an amplifier. The system may include a loop filter; a driver; a digital-to-analog converter (DAC) configured to source and to sink current; an edge selector configured to determine a first delay between the driver receiving a signal to provide a driver output signal and the driver providing the driver output signal; a timing circuit configured to determine a second delay between the DAC receiving a signal to provide a DAC output current and the DAC providing the DAC output current; and at least one controller configured to control the DAC to source or to sink the DAC output current at a time corresponding to a beginning of the driver output signal, and control the DAC to stop sourcing or sinking the DAC output current at a time corresponding to an end of the driver output signal.

### CROSS-REFERENCE TO RELATED APPLICATIONS

This application claims priority to U.S. Provisional Application No. 63/385,925, titled LOOP FILTER ASSIST CIRCUIT, filed on Dec. 2, 2022, and incorporated herein by reference in its entirety for all purposes.

### BACKGROUND

### 1. Field of the Disclosure

At least one example in accordance with the present disclosure relates generally to reducing error in electric signals.

### 2. Discussion of Related Art

Class-D amplifiers are amplifiers that use the switching characteristics of transistors rather than the non-linear gain of transistors to amplify electric signals.

### SUMMARY

According to at least one aspect of the present disclosure, a system for mitigating error in an amplifier is presented, the system comprising: a loop filter having a differential output; a driver coupled to the loop filter and configured to provide a drive signal to the loop filter; a digital-to-analog converter (DAC) coupled to the differential output and configured to source and sink current on the differential output; a delay detection circuit configured to determine a drive delay; and at least one controller configured to determine an output of the DAC based on the drive signal, and control the DAC to source or sink current on the differential input based on the drive delay.

In some examples, the delay detection circuit includes an edge selector configured to determine the drive delay based on a first time when the driver receives a signal to provide the drive signal and a second time when the driver begins providing the drive signal. In some examples, the delay detection circuit includes a timing circuit configured to determine a DAC delay based on a first time when the DAC receives a signal to source or sink a current and a second time when the DAC begins to source or sink the current. In some examples, the delay detection circuit is further configured to determine a DAC delay, the differential output includes a first differential output and a second differential output, the DAC includes a first source and a first sink coupled to the first differential output, the first source configured to source current on the first differential output, and the first sink configured to sink current on the first differential output, the DAC includes a second source and a second sink coupled to the second differential output, the second source configured to source current on the second differential output, and the second sink configured to sink current on the second differential output. In some examples, the driver includes a first driver output connection coupled to the loop filter and a second driver output connection coupled to the loop filter, and the DAC includes a first DAC coupled to the differential output and a second DAC coupled to the differential output. In some examples, the first DAC is configured to provide a first DAC output signal when a first differential voltage is present across the first driver output connection and the second driver output connection, and the second DAC is configured to provide a second DAC output signal when a second differential voltage is present across the first drive output connection and the second driver output connection. In some examples, one of the first differential voltage and the second differential voltage is zero or approximately zero. In some examples, the DAC includes at least one current source configured to shape a DAC current, and to source or sink the DAC current, wherein the DAC current is shaped based on a time-constant of the DAC.

According to at least one aspect of the present disclosure, a system for mitigating error in an amplifier is presented, the system comprising an input; a control circuit configured to determine a delay between receiving an input signal at the input and providing an output signal at an output; and an assist digital-to-analog converter (“assist DAC”) configured to source or sink current based on the input signal.

In some examples, the delay includes a first delay and a second delay, the first delay being a period of time between a driver receiving a signal to provide the input signal and the driver providing the input signal, and the second delay being a period of time between the assist DAC receiving a signal to source or sink current and the assist DAC sourcing or sinking current. In some examples the control circuit includes an edge selector configured to determine the first delay and a timing circuit configured to determine the second delay. In some examples, the control circuit controls the assist DAC to source or sink current when the driver is providing the input signal. In some examples, the control circuit controlling the assist DAC to source or sink current when the input signal is present includes the control circuit accounting for the first delay and the second delay, wherein accounting for the first delay and the second delay includes minimizing an amount of time the assist DAC sources or sinks current during which the driver is not providing the input signal. In some examples, the assist DAC includes a plurality of DACs, each DAC of the plurality of DACs having a respective source and a respective sink. In some examples, the system further comprises an integrator coupled between the input and the output.

According to aspects of the present disclosure, a method of minimizing feedback error in an amplifier is presented, the method comprising: providing a driver control signal to a driver, the driver control signal instructing the driver to provide a driver output; providing the driver output from the driver responsive to receiving the driver control signal; determining a delay between providing the driver control signal to the driver and the driver providing the driver output; determining a polarity of the driver output; sourcing a first current responsive to determining that the polarity is positive; and sinking a second current responsive to determining that the polarity is negative.

In some examples, the method further comprises sourcing the first current or sinking the second current based on the delay. In some examples, sourcing the first current or sinking the second current based on the delay includes sourcing or sinking a current by using the delay to determine when the driver will begin providing the driver output, and timing sourcing or sinking the current to correspond to when the driver begins providing the driver output. In some examples, the method further comprises determining a source delay or a sink delay, wherein the source delay is a first amount of time between providing a source control signal and sourcing the first current, and the sink delay is a second amount of time between providing a sink control signal and sinking the second current. In some examples, sourcing the first current based on the delay includes sourcing the first current based on the source delay by using the source delay to determine when the first current will begin to be sourced and timing the first current to begin to be sourced to correspond to when the driver begins to provide the driver output, and wherein sinking the second current based on the delay sinking the second current based on the sink delay by using the sink delay to determine when the second current will being to be sinked and timing the second current to begin to be sinked to correspond to when the driver begins to provide the driver output.

According to at least one aspect of the present disclosure a system for mitigating error in an amplifier is provided. In some examples, the system for mitigating error in an amplifier comprises a loop filter having a differential output; a driver coupled to the loop filter; a digital-to-analog converter (DAC) coupled to the differential output and configured to source and to sink current to at least one output of the differential output; an edge selector configured to determine a first delay between the driver receiving a signal to provide a driver output signal and the driver providing the driver output signal; a timing circuit configured to determine a second delay between the DAC receiving a signal to provide a DAC output current and the DAC providing the DAC output current; and at least one controller configured to determine a voltage for the DAC output current based on a voltage of the driver output signal, control the DAC to source or to sink the DAC output current at a time corresponding to a beginning of the driver output signal, and control the DAC to stop sourcing or sinking the DAC output current at a time corresponding to an end of the driver output signal.

In some examples, the DAC includes a first DAC having a first source and a first sink, the first source configured to source the DAC output current to the at least one output of the differential output and the first sink configured to sink the DAC output current from the at least one output of the differential output, and a second DAC having a second source and a second sink, the second source configured to source the DAC output current to the at least one output of the differential output and the second sink configured to sink the DAC output current from the at least one output of the differential output.

In various examples, the first DAC does not provide the DAC output current when the driver is not providing an output signal and the second DAC provides the DAC output current when the driver is not providing an output signal. In many examples, the second DAC does not provide the DAC output current when the driver is providing an output signal and the first DAC is provides the DAC output current when the driver is providing an output signal. In some examples, the DAC includes at least one current source configured to shape a DAC output current into a shaped DAC output current, and provide the shaped DAC output current to the at least one output. In various examples, the shaped DAC output current is shaped based on an RC time constant of the system.

In many examples, the system further comprises an audio assist DAC coupled to at least one output of the differential output of the loop filter and a pulse assist DAC coupled to at least one output of the differential output of the loop filter, the audio assist DAC being configured to provide an output signal to the at least one output when no differential voltage exists between a first pin and a second pin of the driver, and the pulse assist DAC being configured to provide an output signal to the at least one output when a differential voltage exists between the first pin and the second pin of the driver. In various examples, controlling the DAC to source or sink the DAC output current at the time corresponding to the beginning of the driver output signal further includes accounting for the first delay and the second delay such that the controller controls the DAC to source or sink the DAC output current such that the DAC outputs the DAC output current at the beginning of the driver output signal without delay.

According to at least one aspect of the present disclosure, a Digital-to-Analog converter (DAC) is presented. In some examples, the DAC comprises an output configured to source or to sink a DAC output current, an edge selector configured to determine a first period of time between a driver receiving a signal to provide a driver output signal and the driver providing the driver output signal; a timing circuit configured to determine a second period of time between the DAC receiving a signal to provide the DAC output current and the DAC providing the DAC output current; and at least one controller configured to determine a voltage for the DAC output current based on a voltage of the driver output signal, control the DAC to source or to sink the DAC output current at a time corresponding to a beginning of the driver output signal, and control the DAC to stop sourcing or sinking the DAC output current at a time corresponding to an end of the driver output signal.

In various examples, the DAC further comprises a first DAC having a first source and a first sink, a second DAC having a second source and a second sink, and wherein the first source is coupled to the second sink and the first sink is coupled to the second source.

According to at least one example in accordance with the present disclosure, a system for mitigating error in an amplifier is provided. In many examples, the system comprises an input; a control circuit configured to determine a delay between receiving an input signal at the input and providing an output signal at an output; and an assist digital-to-analog converter (“assist DAC”) configured to source or sink current based on the input signal.

In various examples, the delay includes a first delay and a second delay, the first delay being a period of time between a driver receiving a signal to provide the input signal and the driver providing the input signal, and the second delay being a period of time between the assist DAC receiving a signal to source or sink current and the assist DAC sourcing or sinking current. In many examples, the control circuit includes an edge selector configured to determine the first delay and a timing circuit configured to determine the second delay. In some examples, the control circuit controls the assist DAC to source or sink current when the input signal is present. In various examples, the control circuit controlling the assist DAC to source or sink current when the input signal is present includes the control circuit accounting for the first delay and the second delay. In many examples, accounting for the first delay and the second delay includes minimizing an amount of time the assist DAC sources or sinks current during which the input signal is not present. In some examples, the assist DAC includes a plurality of DACs, each DAC of the plurality of DACs having a respective source and a respective sink. In various examples, the system further comprises an integrator coupled between the input and the output. In many examples, the control circuit is further configured to determine a voltage for the assist DAC to use to source or sink current.

According to at least one example in accordance with the present disclosure, a method of sourcing and sinking current is presented. In some examples, the method comprises determining a delay between receiving an input signal and sourcing or sinking a current; determining a polarity of the input signal; sourcing the current responsive to determining that the polarity is positive and sinking a current responsive to determining that the polarity is negative; and accounting for the delay to determine when to source or sink the current.

In various examples, determining the delay includes determining a first delay corresponding to a driver receiving a signal to provide the input signal and the driver providing the input signal, and determining a second delay corresponding to receiving the signal to source or sink the current and sourcing or sinking the current. In many examples, accounting for the delay includes using the first and second delays to minimize the amount of time during which current is sourced or sunk and the input signal is not present.

### BRIEF DESCRIPTION OF THE DRAWINGS

Various aspects of at least one embodiment are discussed below with reference to the accompanying figures, which are not intended to be drawn to scale. The figures are included to provide an illustration and a further understanding of the various aspects and embodiments, and are incorporated in and constitute a part of this specification, but are not intended as a definition of the limits of any particular embodiment. The drawings, together with the remainder of the specification, serve to explain principles and operations of the described and claimed aspects and embodiments. In the figures, each identical or nearly identical component that is illustrated in various figures is represented by a like numeral. For purposes of clarity, not every component may be labeled in every figure. In the figures:

FIG. 1 illustrates a class-D amplifier according to an example;

FIG. 2 illustrates a system for eliminating error components in signals according to an example;

FIG. 3 illustrates a block diagram of an assist DAC control architecture according to an example;

FIG. 4 illustrates an assist DAC according to an example;

FIG. 5 illustrates a schematic diagram of two current sources according to an example;

FIG. 6 illustrates a flowchart of a process for reducing error at the output of an integrator according to an example; and

FIG. 7 illustrates an embodiment of a class-D amplifier having an assist DAC according to an example.

### DETAILED DESCRIPTION

Examples of the methods and systems discussed herein are not limited in application to the details of construction and the arrangement of components set forth in the following description or illustrated in the accompanying drawings. The methods and systems are capable of implementation in other embodiments and of being practiced or of being carried out in various ways. Examples of specific implementations are provided herein for illustrative purposes only and are not intended to be limiting. In particular, acts, components, elements and features discussed in connection with any one or more examples are not intended to be excluded from a similar role in any other examples.

Also, the phraseology and terminology used herein is for the purpose of description and should not be regarded as limiting. Any references to examples, embodiments, components, elements or acts of the systems and methods herein referred to in the singular may also embrace embodiments including a plurality, and any references in plural to any embodiment, component, element or act herein may also embrace embodiments including only a singularity. References in the singular or plural form are not intended to limit the presently disclosed systems or methods, their components, acts, or elements. The use herein of “including,” “comprising,” “having,” “containing,” “involving,” and variations thereof is meant to encompass the items listed thereafter and equivalents thereof as well as additional items.

References to “or” may be construed as inclusive so that any terms described using “or” may indicate any of a single, more than one, and all of the described terms. In addition, in the event of inconsistent usages of terms between this document and documents incorporated herein by reference, the term usage in the incorporated features is supplementary to that of this document; for irreconcilable differences, the term usage in this document controls.

Class-D amplifiers, and other electronic devices, may experience feedback error due to constituent parts of the amplifier. For example, processing of currents that are used as inputs to an integrator or loop filter may include error components caused by the processing. In some examples, the errors may be caused by the loop filter processing the currents. To minimize the error, such that the errors are not amplified during the feedback process, an assist DAC can provide identical currents at the output of the integrator or loop filter as there are at the inputs. Because current entering a node equals current exiting a node, by providing equal current at both the input and output, no current or minimal current may pass through the loop filter or integrator, and thus the feedback error may be minimized or eliminated.

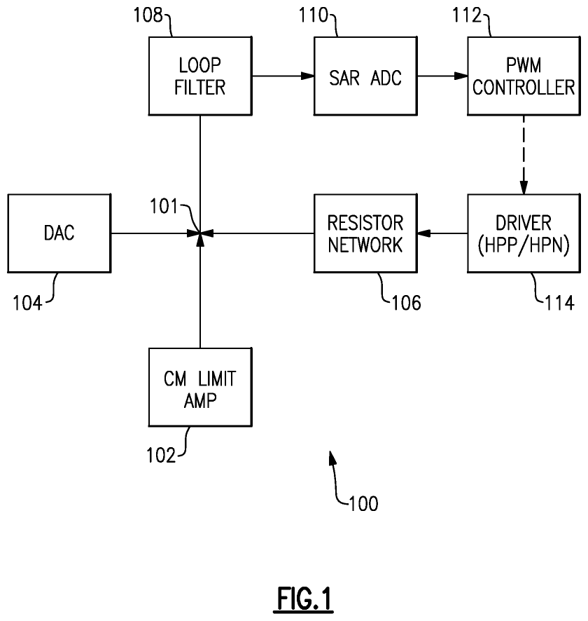

FIG. 1 illustrates a class-D amplifier 100 according to an example. The amplifier 100 includes a Common Mode (CM) limit amplifier 102, a digital-to-analog converter (DAC) 104, a resistor network 106, a loop filter 108, a successive approximation register analog-to-digital converter (SAR ADC) 110, a pulse width modulation (PWM) controller 112, and a driver 114.

There is also a summing node 101. The summing node 101 is where the outputs of the CM limit amplifier 102, DAC 104, and resistor network 106 are summed.

The amplifier 100 may be self-regulating. That is, the PWM controller 112 may control the output of the driver 114 based, at least in part, on the output of the driver 114. In some examples, the output of the driver 114 may be fed back to the PWM controller 112 via a loop (such as the loop filter 108). The PWM controller 112 can then control the output of the driver 114 based on the fed-back output. The driver 114 in the amplifier 100 may be driven by different supply voltages, and those supply voltages may change (i.e., be switched) depending on the output and input to the amplifier.

The CM limit amplifier 102, DAC 104, and resistor network 106 are coupled to the loop filter 108. The loop filter 108 is coupled to the SAR ADC 110. The SAR ADC 110 is coupled to the PWM controller 112, and the PWM controller 112 is configured to control the driver 114. In some examples, the PWM controller 112 may be coupled to the driver 114. Each of the CM limit amplifier 102, DAC 104, resistor network 106, and driver 114 may provide differential outputs. The CM limit amplifier 102, DAC 104, and resistor network 106 provide a differential output to the loop filter 108. The driver 114 provides a differential output to the resistor network 106. In some examples, the loop filter 108 may provide a differential output to the SAR ADC 110. The SAR ADC 110 may provide a digital audio signal to the PWM controller 112.

The PWM controller 112 controls the output of the driver 114. The driver 114 may produce pulses, for example square wave pulses, based on inputs from the PWM controller 112. The driver 114 provides its output to the resistor network 106. The resistor network 106 then provides the output to the summing node 101. The summing node 101 also receives the outputs of the DAC 104 and CM limit amplifier 102. All of these outputs summed at the summing node 101 are then provided to the loop filter 108, which processes the outputs and provides an analog waveform to the SAR ADC 110. The SAR ADC 110 converts the waveform from analog to digital, where the PWM controller 112 can receive the digitized waveform and use it to determine how to control the driver 114. In this fashion, the amplifier 100 may operate as a feedback architecture that can adjust the output of the driver 114 based on feedback from the driver 114 and other parts of the circuit (e.g., the DAC 104 and CM limit amplifier 102).

The driver 114 may be an H-bridge driver and may include at least two pins, including HPP and HPN pins. The HPP pin is a positive pin, and the HPN pin is a negative pin. In some examples, the PWM controller 112 controls the driver 114 to produce a square wave of alternating polarity at the pins of the driver 114. The pins can output a non-zero voltage or a zero voltage. Depending on the requirements of the circuit using the class-D amplifier 100, for example an audio circuit, the driver 114 may switch between various supply voltages and ground. For example, one supply voltage may be ±0.7V, and another supply voltage may be ±1.3V, another may be ±2.5V, and so forth. The PWM controller 112 may, in some examples, control which voltage supply is used to supply the voltage to the driver 114.

In some examples, due to defects (such as fabrication errors or variances) in the loop filter 108 or CM limit amplifier 102, different supply voltages may have different errors, where error is defined as the difference between the actual voltage and the ideal voltage of the amplifier 100. For example, the error may be 50 uV for the 0.7V supply voltage, but may be 500 uV for the 1.3V supply voltage. As a result, switching between supply voltages may cause a substantial increase in error, which may cause distortions, such as pops and clicks in an audio application and may be manifested in other errors in applications other than audio application. However, this error can be eliminated. This error can be categorized into two parts, as discussed below.

The summing node 101 acts as a virtual ground for the loop filter 108. The loop filter 108 has bandwidth and gain constraints related to its physical construction and properties. As a result, a differential error can exist between the inputs of the loop filter 108 at the summing node 101. The summing node 101 may be a differential summing node, since the outputs of the CM limit amplifier 102, DAC 104, and resistor network 106 may be differential. The differential error at the virtual ground (the summing node 101) is translated directly to the output voltage. Said error may be referred to as the loop filter induced error.

The CM limit amplifier 102 also creates a differential error that is related to the loop filter induced error but has a different cause. The differential error at the summing node 101 interacts with the finite impedance of the CML 102. The interaction creates an error current that is multiplied by the input resistor network 106 and creates an error at the output of amplifier 100. This error is referred to as the CML induced error.

Both errors may be carried through or multiplied by the loop filter 108. The loop filter 108 can provide the erroneous signal to the SAR ADC 110 and thence to the PWM controller 112, which can lead to the PWM controller 112 improperly adjusting the driver 114 because the feedback signal from the loop filter 108 is erroneous. As mentioned, the error, processed in this way, can cause undesirable noise at the output of the driver 114.

One way to eliminate the error (both loop filter induced error and CML induced error) is to increase the power of the system. Providing more power through the loop filter will cause a less differential voltage error in all cases and for all voltage supplies. That is, an error caused by a jump from 500 uV to 50 uV may be reduced to a jump from 50 uV to 5 uV by increasing power to the loop filter. This method reduces the magnitude of the error but does not resolve the error. Furthermore, throwing power at the problem can be inefficient, and in applications where power is provided by a battery, may dramatically shorten the runtime of the device in which it is incorporated. Another solution is to eliminate or minimize the current passing through the loop filter, so that the error is minimized or eliminated.

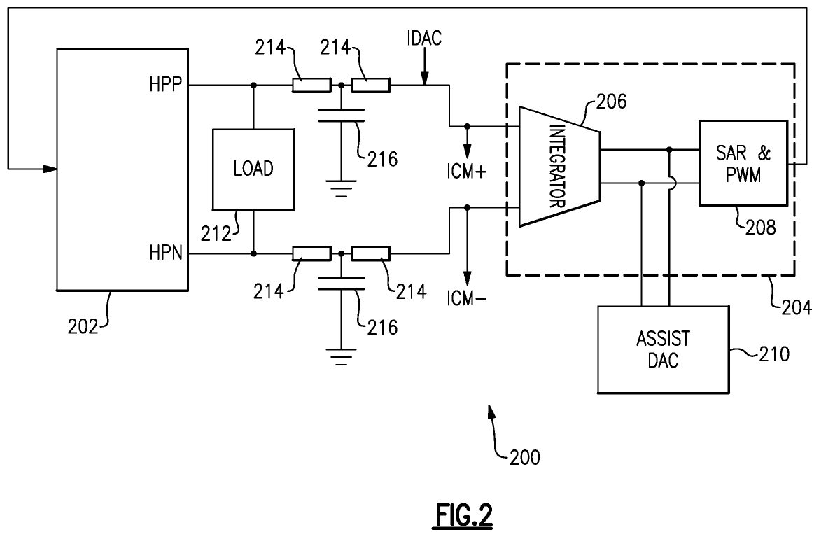

FIG. 2 illustrates a system 200 that can eliminate the errors described with respect to FIG. 1. FIG. 2 includes a driver 202, such as an H-bridge driver, with HPP and HPN pins, a loop filter 204 including an integrator 206 and the SAR ADC and PWM components 208 (“PWM 208”) of the system 200. The system 200 also include an assist DAC 210, a load 212, resistors 214 (such as the resistors of the resistor network 106), capacitors 216, and pins which connect to a DAC (the IDAC input) and CM limit amplifier (ICM+ and ICM−, with ICM+ being the positive input and ICM− being the negative input). In some examples, the capacitors 216 may be or include parasitic capacitances. In some examples, the load 212 may include headphones, speakers, or other audio output devices.

In the system 200, the integrator 206 may receive signals originating from other parts of the circuit (e.g., the HPP and HPN pins, and other places-such as the DAC 104 or CM limit amplifier 102 of FIG. 1). These signals may result in current at the inputs of the integrator 206. The assist DAC 210 provides matching currents at the outputs of the integrator 206 so that no or minimal current flows through the integrator 206. By minimizing or eliminating current flowing through the integrator 206, CML induced error, loop filter induced error, and error due to the driver supply voltage switching from one level to another level may be minimized or eliminated.

The driver 202 is coupled to the loop filter 204 via the PWM 208, the load 212, and the resistors 214. The resistors 214 are coupled to the load 212, other resistors 214, and the capacitors 216. Some of the resistors 214 are coupled to the IDAC, ICM+, ICM− pins, and the integrator 206. The integrator is coupled to the PWM 208 and the assist DAC 210. The assist DAC is also coupled to the PWM 208.

To understand operation of the system 200, first consider the system without the assist DAC 210. The driver 202 provides an output at either HPP or HPN, but not both at the same time. This is typical of a class-D amplifier, where the positive signal (HPP) is driven or the negative signal (HPN) is driven, but both are not, thus producing an oscillating signal, such as a square wave. Over time, the average current into the integrator 206 may be zero, but instantaneously the current may not be zero. In some examples, in any one clock period the integrator 206 may integrate two different currents. When the pulse from the driver 202 is not active, the integrator may integrate current from an audio DAC (i.e., IDAC). When the pulse from the driver 202 is active, the integrator may integrate the difference between the audio DAC current and the input network current (which is the current provided through the resistors 214 from the driver 202 to the integrator 206).

For any DC voltage, the error voltage of the loop filter 204 is determined by the audio DAC current, the pulse width of the driver's 202 output, and the supply voltage of the driver 202. If the input to the integrator 206 changes slightly while not changing supply voltage, only slight changes will occur in the audio DAC current and in the pulse width. As a result, the error will slowly change in a manner that presents like a weak non-linearity, and will not cause “pops,” “clicks,” or other errors that are addressed by the system 200. However, if a change in the input causes a supply voltage change (e.g., the driver 202 switches from one supply voltage, such as 0.8V, to another supply voltage, such as 1.2V) to vary more appreciably, the audio DAC current will change only slightly, but the pulse width and/or amplitude may change dramatically. For example, going from a lower to higher supply voltage, and aiming to keep total energy constant, the pulse width would fall in proportion to the increase in voltage. That is, total energy provided by the pulse from the driver 202 being unchanged, a change from 0.5V to 1V may result in the pulse width being halved. The dramatic change in pulse width can cause the error to change significantly, which may cause “pops,” “clicks,” and other errors that the system 200 addresses.

The assist DAC 210 solves the error problem. Since the error is generally due to different currents and pulse widths being provided to the input of the loop filter 204, and more particularly to the input of the integrator 206, eliminating the current can reduce or eliminate the error. The assist DAC 210 eliminates the current by providing currents which match the input current to the integrator 206 at the output of the integrator 206. Since the current entering a node equals the current exiting a node, by providing matching current at the output of the integrator 206 the assist DAC 210 prevents most or any current from passing through the integrator 206. If current does flow through the integrator 206, the current should be much smaller than it would otherwise be, and the errors will be smaller and thus less significant, resulting in an overall improvement in signal and/or audio quality.

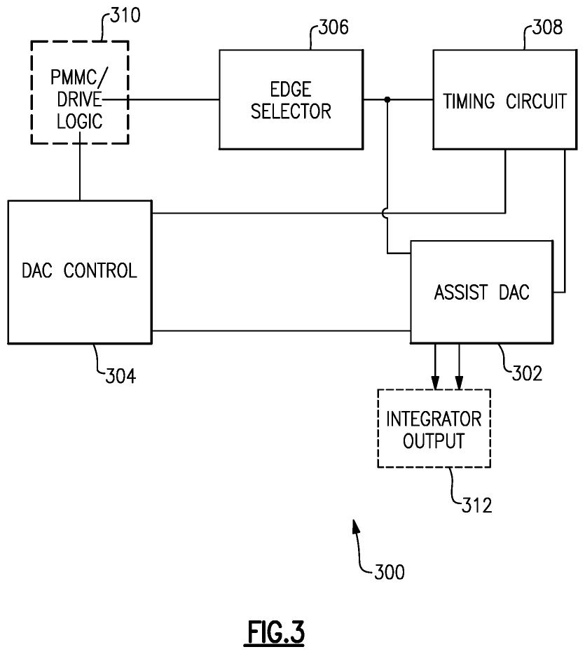

Assist DACs, such as assist DAC 210, will be discussed in greater detail with respect to FIGS. 3-5, and elsewhere herein.

The current provided by the driver 202 to the loop filter 204 may have a resistive-capacitive (RC) time constant associated with it. Those of skill in the art will recognize that the system 200 has both resistors 214 and capacitors 216, and thus the capacitors will take time to charge and discharge. The RC time constant is a value based on the resistance and capacitance of the resistors 214 and capacitors 216, and is relevant to many different calculations and values in electromagnetic theory. The RC time constant, in particular, has a direct impact and relationship to the time it takes the capacitors to charge and discharge. As a result, the current provided by the driver 202 to the loop filter 206 via the resistors 214 will be shaped in a manner directly related to the RC time constant. In particular, in some examples, the current provided by the driver 202 may not instantly equal the total current given a particular voltage. Instead, the current may increase or decrease more slowly as the capacitor charge and discharges.

Current provided by the assist DAC 210 may be shaped as well, to match the shaping of the current provided by the driver 202 to the integrator 206. While the current provided by the assist DAC 210 need not be shaped, shaping the current will advantageously prevent the assist DAC 210 from providing too much current to the output of the integrator 206 while the current provided at the input of the integrator 206 is still increasing or decreasing as the capacitors 216 charge or discharge. In some examples, by shaping the current from the assist DAC 210, the current from the assist DAC 210 can be made to increase and decrease in the same manner as the current received at the input of the integrator 206 from the driver 202, thus providing a better match between the currents at the input and output of the integrator 206, thereby assisting to reduce and/or further reducing the current flowing through the integrator 206.

With the current passing through the integrator 206 near zero, the PWM 208 will not provide a feedback signal to the driver 202 that includes an error component. Alternatively, the error component of the feedback signal provided by the PWM 208 to the driver 202 will be minimized and/or reduced. As a result, signals, such as audio signals, produced by the driver 202 will not include substantial error components that could cause “pops” or “clicks” or other unwanted noises in the example where the load 212 is a speaker when the supply voltage of the driver 202 switches.

FIG. 3 illustrates a block diagram of an assist DAC control architecture 300 (“DAC architecture 300”) according to an example. The DAC architecture 300 includes an assist DAC 302, a DAC control 304, an edge selector 306, and a timing circuit 308. Also shown are the PWM controller and Driver control logic 310 (“PWMC 310”) and the integrator output 312.

The assist DAC 302 may operate as a current source, providing current to the appropriate lines of the differential output of the integrator (e.g., integrator 206). The integrator output 312 represents the output of the integrator (e.g., integrator 206). The DAC control 304 provides delay line codes, disable signal, amplitude control, and other controls of the assist DAC 302. The timing circuit 308 determines when the assist DAC 302 should provide current to the integrator output 312. The edge selector 306 detects edges of signals originating from the driver (e.g., driver 114, and provides additional control and timing functions. By combining the functions of the circuits mentioned above, the assist DAC 302 is able to provide the appropriate amount of current to the integrator output 312, thus minimizing loop filter induced errors, CML induced errors, and/or other errors due to switching the voltage supply of the driver.

The assist DAC 302 may be coupled to the DAC control 304, edge selector 306, and timing circuit 308. The assist DAC 302 may also be coupled to the integrator output 312, which may be the output of an integrator such as the integrator 206 of FIG. 2. The DAC control 304 may be coupled to the assist DAC 302, timing Circuit 308, and PWMC 310. The edge selector 306 may be coupled to the PWMC 310, timing circuit 308, and assist DAC 302. The timing circuit 308 may be coupled to the edge selector 306, DAC control 304, and assist DAC 302. In some examples, circuit components mentioned above may also be coupled to other parts of the circuit, or may receive signals originating from other parts of the circuit or to provide signals to other parts of the circuit. For example, the DAC control 304 may receive signals from or provide signals to the edge selector 306.

The assist DAC 302 provides current to the integrator output 312. The current provided by the assist DAC 302 equals or approximately equals current at the input of the integrator. The assist DAC 302 may be bipolar, meaning that the assist DAC 302 may source (provide or push) or sink (receive or pull) current from the integrator output 312. The assist DAC 302 may further be differential, and may treat each differential output differently. That is, if the integrator output 312 is differential, having two or more lines (the lines typically, but not necessarily, having different polarities), the assist DAC may source current on one line and sink current on another line.

The assist DAC 302 may take time to activate relative to when a pulse (and therefore a current) is provided to the input of the integrator. It is desirable to activate the assist DAC 302 at the same time a pulse is received at the input to the integrator, thus ensuring the assist DAC 302 provide an equal current only during the period of time that sourcing or sinking a current at the input of the integrator is necessary. Activating the assist DAC 302 at the appropriate time also may ensure the output signal of the assist DAC 302 is in phase with the signal input into the integrator. However, detecting when to turn on the assist DAC 302 may be difficult due to delays, such as a driver delay and an assist DAC delay.

The driver delay may include the period of time it takes the driver (e.g., driver 114) to turn on. The driver delay may include the time it takes for a signal to reach the final gate of the driver so as to output at the output of the driver. The assist DAC delay may include the period of time it takes the assist DAC 302 to turn on. The assist DAC delay may, therefore, include the time between when the assist DAC 302 receives an instruction and/or signal (such as an enable signal) to provide an output and when the assist DAC 302 begins providing the output.

The edge selector 306 may determine the time between when the driver (e.g., driver 114) receives an instruction and/or signal to provide output and when the driver begins to provide output. In some examples, the edge selector 306 may determine when a pulse is occurring, such as a pulse occurring at the output of the driver. In some examples, the edge selector 306 may receive a first input corresponding to a pulse occurring at a pin of the driver (e.g., HPP and/or HPN pins). In some examples, the edge selector 306 may also receive inputs corresponding to the driver control inputs—that is, in some examples, the edge selector 306 may also receive the driver control signals that control the driver to provide an output. In some examples, the edge selector 306 may monitor signals coming into the driver as well as the actual gates of the switching transistors (of the driver) themselves. Using the inputs and/or signals described above, the edge selector 306 can extract the driver delay by determining how long it takes for the driver to be instructed to activate compared to when the driver begins to output. The edge selector 306 may provide signals indicative of the driver delay to the timing circuit 308 and/or assist DAC 302.

In some examples, the edge selector 306 may compare the driver delay to the switching characteristics of a replica RC current DAC. By comparing the driver delay to the switching characteristics of a replica RC current DAC, the signals provided by the assist DAC 302 may be shaped to avoid providing too much current to the integrator output 312. The edge selector 306 may provide a pulse enable signal to the assist DAC 302, controlling the assist DAC to output a pulse. Because the edge selector 306 may receive signals indicative of the driver outputting, the edge selector 306 may provide the pulse enable signal to the assist DAC 302 when the driver is outputting. In some examples, the replica RC current may be provided by the assist DAC 302 or may be based on the frequency response of the assist DAC 302 itself. In some examples where the assist DAC 302 provides the replica RC current, the assist DAC 302 may provide the replica RC current to delay lines and feed the current back to the timing circuit 308 or edge selector 304.

In various examples, the replica current may be supplied by an independent current source, for example, an independent current source co-located in the assist DAC 302. The replica current source may provide current equal to the least-significant bit of the assist DAC 302.

The timing circuit 308 determines timing characteristics of the driver (e.g., driver 114) and/or assist DAC 302. The timing circuit 308 may determine the assist DAC delay and/or driver delay. In some examples, the timing circuit 308 uses the signals indicative of driver delay provided by the edge selector 306 to determine timing characteristics of the driver and/or assist DAC 302. The timing circuit 308 uses the timing signals and/or information to enable and disable the sinks and sources of the assist DAC 302. In some examples, the timing circuit 308 receives replica currents from the assist DAC 302 and/or the replica RC current DAC, and uses the replica currents to determine the timing characteristics of the assist DAC 302. For example, using the replica currents the timing circuit 308 may determine the assist DAC delay. In some examples, the timing circuit 308 may receive the pulse enable signal from the edge selector 306, and compare the time between when the pulse enable signal is received and when the replica DAC current is received to determine the assist DAC delay. The timing circuit 308 may use the control signals controlling the sinks and sources of the assist DAC 302 (such as enabling or disabling the sinks or sources) to prevent the assist DAC 302 from providing a signal when the driver is not outputting.

The DAC control 304 may control which delay lines are active, and may provide delay line codes. In some examples, the DAC control 304 may provide delay line codes to the timing circuit 308, and the timing circuit 308 may use the delay line codes to determine timing characteristics of the assist DAC 302 and/or determine when to provide control signals activating or deactivating the sources or sinks of the assist DAC 302.

The DAC control 304 may determine the output voltage for the assist DAC 302. That is, when the assist DAC 302 provides a pulse or current to the integrator output 312, the DAC control 304 may control the assist DAC 302 to provide the pulse or current at a particular supply voltage. The DAC control 304 may receive an indication, for example a control signal, of the supply voltage of the driver (e.g., driver 114). The DAC control 304 may control the assist DAC 302 to provide the pulse or current to the integrator output 312 with the pulse or current having a voltage equal to the supply voltage of the driver.

In some example, the voltage provided at the output of the driver (e.g., driver 202) may be less than the nominal supply voltage. That is, the supply voltage may be 1.7 volts, but the voltage at the output of the driver that is presented to the integrator (e.g., integrator 206) may be 1.5 volts. The difference between the nominal supply voltage and the voltage at the driver output may be due to the internal resistance of components. The voltage drop due to the internal resistance is called the IR drop. The DAC control 304 may be configured to determine the IR drop in the driver so that the output voltage of the assist DAC 302 can be set to be close to the actual voltage at the input of the integrator rather than the supply voltage. To determine the IR drop, the DAC control 304 may use a resistance value corresponding to a resistance of the driver as seen from the load (e.g., driver 202 and load 212) and measure the load current. The resistance value may be scaled by a factor. The DAC control 304 may multiply the headphone current by the resistance value to determine the voltage at the output of the driver, and then may provide signals to the assist DAC 302 to cause the assist DAC 302 to alter its output, for example, by changing the pulse width of the output of the assist DAC 302.

In some examples, the difference in the supply voltage is estimated by comparing the ideal duty cycle (i.e., the duty cycle without IR drop) to the observed duty cycle (i.e., the duty cycle with IR drop). The difference between the two values and the current is used to estimate the resistance of the driver (e.g., driver 202). The resistance of the driver may then be used to compensate of the IR drop in real-time. The function of determining IR drop may operate in the background and be performed continuously.

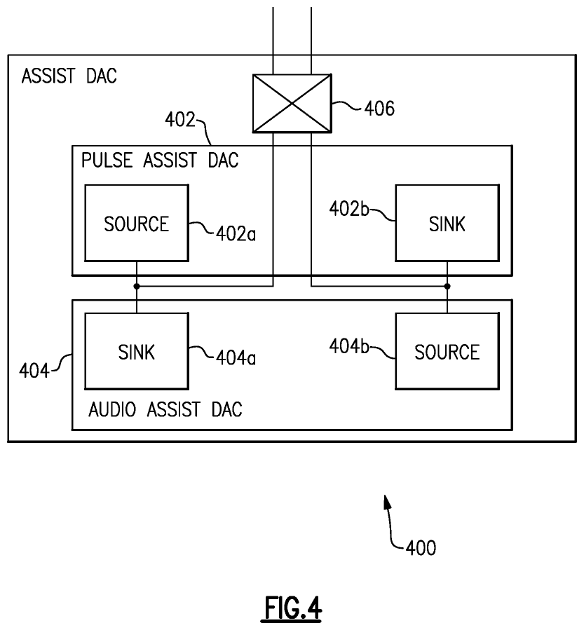

In some examples, the DAC control 304 may also control which sources and sinks of the assist DAC 302 are active or inactive. In some examples, the DAC control 304 may control which DACs within the assist DAC 302 are active or inactive. The DACs within the assist DAC 302, and the sources and sinks of the assist DAC 302 will be discussed in greater detail with respect to FIG. 4.

FIG. 4 illustrates an assist DAC 400 according to an example. The assist DAC 400 includes a pulse assist DAC 402 (“pulse DAC 402”), an audio assist DAC 404 (“audio DAC 404”), and a differential output 406 (“output 406”). The pulse DAC has a pulse DAC source 402a (“pulse source 402a”) and a pulse DAC sink 402b (“pulse sink 402b”). The audio DAC 404 has an audio DAC sink 404a (“audio sink 404a”) and an audio DAC source 404b (“audio source 404b”). The sources and sinks are current sources that may source (that is provide or push) or sink (that is receive or pull) current. In general, the sources 402a, 404b source current and the sinks 402b, 404a sink current.

The pulse source 402a is coupled to the audio sink 404a and to the output 406. The audio sink 404a is coupled to the output 406 as well. The assist sink 402b and audio source 404b are coupled to each other and to the output 406. The output 406 may further be connected to, for example, the differential output of the integrator (e.g., integrator 206). In some examples, the pulse source 402a and audio sink 404a are coupled to a first output of the differential output of the integrator, and the pulse sink 402b and audio source 404b are coupled to output of the differential output of the integrator via the output 406.

The assist DAC 400 may be controlled and/or configured to source or sink currents depending on the conditions of the integrator and the rest of the circuit. For the purposes of clarity and explanation, reference will be made to elements of FIGS. 1 and 2 in the following discussion. Note that the audio DAC 404 is not the same as the audio DAC mentioned with respect to FIG. 2 and the IDAC input to the system 200 in FIG. 2. In the following discussion, the audio DAC of FIG. 2 will be referred to as the IDAC.

As mentioned above, the system 200 can receive inputs from the driver 202, the IDAC, and/or a CM limit amplifier via the ICM+ and ICM− connections. For example, the differential input to the integrator 206 may be the summing node 101 of FIG. 1, and the IDAC may be the DAC 104, and the ICM+ and ICM− connections may be the outputs of the CM limit amplifier 102, and so forth. The audio DAC 404 may be active when there is no differential voltage at the driver 202 (that is, the HPP and HPN pins do not have a differential voltage between them). In some examples, the pulse DAC 402 may be inactive when there is no differential voltage at the driver 202. In some examples, the pulse DAC 402 may be active when there is a differential voltage at the driver 202. In some examples, the audio DAC 404 may be inactive when there is a differential voltage at the driver 202. In some examples, a controller, such as the DAC control 304, may provide control signals enabling or disabling the audio DAC 404 and pulse DAC 402 according to the presence or absence of a differential voltage at the driver 202.

Accordingly, in some examples, when the pulse DAC 402 is active, the pulse source 402a sources a current to the first output of the integrator 206 and the pulse sink 402b sinks a current from the second output of the integrator 206. In some examples, when the audio DAC 404 is active, the audio sink 404a sinks a current from the first output of the integrator 206 and the audio source 404b sources a current to the second output of the integrator 206.

The current and current pulses provided by the assist DAC 400 may be shaped. In some cases, the assist DAC 400 will provide a square-wave pulse. However, a standard square-wave signal may provide too much energy to the output of the integrator 206. For example, the assist DAC 400 may not be able to turn on at exactly the same time a differential voltage (that is, a pulse) exists at the output of the driver 202, or may not be able to turn off at exactly the same time the differential voltage (that is, pulse) no longer exists at the output of the driver 202. As a result, the assist DAC 400 may provide a signal with too large an amplitude when no pulse is present, or too little an amplitude when a pulse is present. Matching the timing of the assist DAC 400 to the driver (e.g., driver 114) using the edge selector 306, timing circuit 308, and/or DAC control 304, may mitigate or eliminate the issue of providing too much energy to the output of the integrator 206.

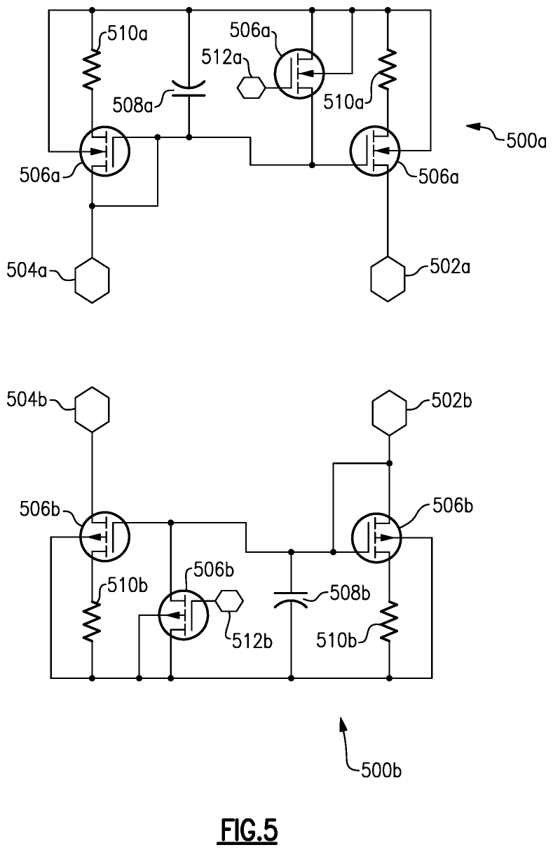

Additionally, the current provided by the sources and sinks of the assist DAC 400 may be shaped to match the shape of the current provided by the driver 202. The shaping may, for example, be shaping with respect to the RC time constant as described with respect to FIG. 2. A circuit for shaping the assist DAC currents will be discussed with respect to FIG. 5.

FIG. 5 illustrates two current sources, a positive bias current source 500a (“pbias source 500a”) and a negative bias current source 500b (“nbias source 500b”).

The pbias source 500a includes an input-output (IO) connection 502a (“IO pin 502a”), a bias input 504a, a plurality of transistors 506a, each transistor of the same type (e.g., each being p-type or each being n-type, and so forth), at least one capacitor 508a, a plurality of resistors 510a, and a gate connection 512a. The nbias source 500b includes an IO connection 502b (“IO pin 502b”), a bias input 504b, a plurality of transistors 506b, each transistor of the same type, at least one capacitor 508b, a plurality of resistors 510b, and a gate connection 512b.

The two current sources 500a, 500b may be substantially identical in some examples, except that the transistors of the nbias source 500b will be of the opposite type relative to the transistors of the pbias source 500a, the bias connections 504a, 504b will be connected to different supply voltages of opposite polarity (and, in some examples, equal magnitude), and the gate connections 512a, 512b may be connected to different control inputs and therefore receive different signals.

The transistors 506a, 506b are coupled to the resistors 510a, 510b, capacitors 508a, 508b, and various connections and pins 502a, 502b, 504a, 504b, 512a, 512b.

The pbias source 500a may provide a positively biased current on the positively biased output of the differential output of the integrator (e.g., integrator 206). The nbias source 500b may provide a negatively biased current to the negatively biased output of the differential output of the integrator. In some examples, the pbias source 500a may source current and the nbias source 500b may sink current.

Both sources 500a, 500b have resistors 510a, 510b and capacitors 508a, 508b. Accordingly, both sources 500a, 500b have a respective RC time constant, and will produce shaped currents. The current sources 500a, 500b are configured to receive a square wave current input, and through the resistors and capacitors, shape the received square wave current and provide the shaped current to the output. In some examples, the sources 500a, 500b are configured to shape the received current in a way that causes the received current to be shaped identically or near-identically to the current received by the integrator 206. In some examples, the sources 500a, 500b may be designed such that the RC constant of the respective source 500a, 500b matches the RC constant of the respective input of the differential input of the integrator 206. The sources 500a, 500b may be implemented in an assist DAC (e.g., assist DAC 210, 302, 400). The sources 500a, 500b may, in some examples, be used to implement the sources (e.g., the sources 402a, 404b of FIG. 4) and/or sinks (e.g., the sinks 402b, 404a of FIG. 4) of a pulse assist DAC (e.g., the pulse assist DAC 402 of FIG. 4) or audio assist DAC (e.g., the audio assist DAC 404 of FIG. 4), and/or any other DAC.

By using the sources 500a, 500b in the sources or sinks, respectively, an assist DAC such as the assist DAC 400 of FIG. 4, can provide shaped current at the output of the integrator that matches the shaped current at the input of the integrator, and therefore minimize current through the integrator, thereby reducing errors and noise.

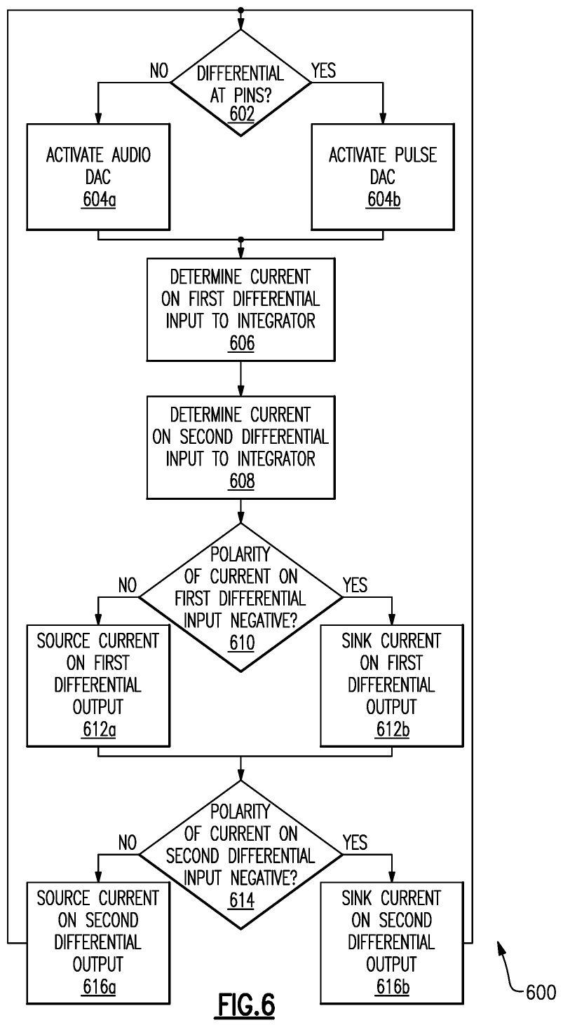

FIG. 6 illustrates a process 600 for reducing error at the output of an integrator.

At act 602, a controller (e.g., any combination of one or more of the DAC control 304, edge selector 306, and/or timing circuit 308) determines whether a differential value, such as a differential current or voltage, exists at the pins (e.g., HPN, HPP). If the controller determines that a differential exists (602 YES), the process 600 may continue to act 604b. If the controller determines that no differential exists (602 NO), the process 600 may continue to act 604a.

At act 604a, controller activates an audio DAC (e.g., audio DAC 404). At act 604b, the controller activates a pulse DAC (e.g., pulse DAC 402). In either case, the activated DACs may be part of an assist DAC (e.g., assist DAC 400), and the process 600 may continue to act 606.

At act 606, the controller determines the current on the first differential input to an integrator (e.g., integrator 206). The integrator may have a first and second differential input, and the current on each differential input may have any polarity, such as negative or positive, at a given time. Thus, the controller determines the amperage and polarity of the current on the first differential input. The process 600 may then continue to act 608.

At act 608, the controller determines the current on the second differential input to the integrator. In some examples, the second differential input may have a current on it that is equal in magnitude but opposite in polarity to the current on the first differential input. In other examples, the polarity and/or magnitude of the current on the second differential input may be the same or different compared to the current on the first differential input. The process 600 may then continue to act 610.

At act 610, the controller determines whether the polarity of the current on the first differential input is negative or positive. If the current is negative (610 YES), the process 600 may continue to act 612b. If the current is positive (610 NO), the process 600 may continue to act 612a.

At act 612a, the controller instructs the audio DAC or assist DAC (whichever was activated during acts 604a or 604b) to source a current on the first differential output corresponding to the first differential input. At act 612b, the controller instructs the audio DAC or assist DAC to sink a current on the first differential output corresponding to the first differential input. When the polarity of the current on the first differential input is negative (610 YES), the controller may instruct the relevant DAC to sink current so that current is flowing away from the differential output to the relevant DAC. In this manner, the current on the first differential input will be negative and the current on the first differential output will be negative, and thus—if the magnitudes of the currents on the input and output are equal or nearly equal, the net current flowing into and out of the integrator between the first differential input and output will be zero or near zero. If the current on the first differential output is positive (610 NO), current may be flowing into the integrator rather than away from it. Accordingly, the controller may instruct the relevant DAC to source current such that positive current is flowing into both the first differential input and the first differential output, such that the net current flowing through the integrator will be zero or near zero. The process 600 may then continue to act 614.

At act 614, the controller determines whether the polarity of the current on the second differential input to the integrator is positive (614 NO) or negative (614 YES). If the current is positive (614 NO), the process 600 may continue to act 616a. If the current is negative (614 NO), the process 600 may continue to act 616b.

Acts 616a and 616b are substantially identical to acts 612a and 612b except that acts 614a and 614b apply to the second differential output and corresponding second differential input of the integrator. From acts 616a or 616b, the process 600 may then return to act 602 and repeat the process 600 periodically, continuously, and so forth.

The acts of process 600 need not occur in the order provided. For example, the determination of polarity (acts 610, 614) can occur in any order with respect to each other, and the controller may determine the currents on the differential inputs in any order, and before or after determining which DAC to activate.

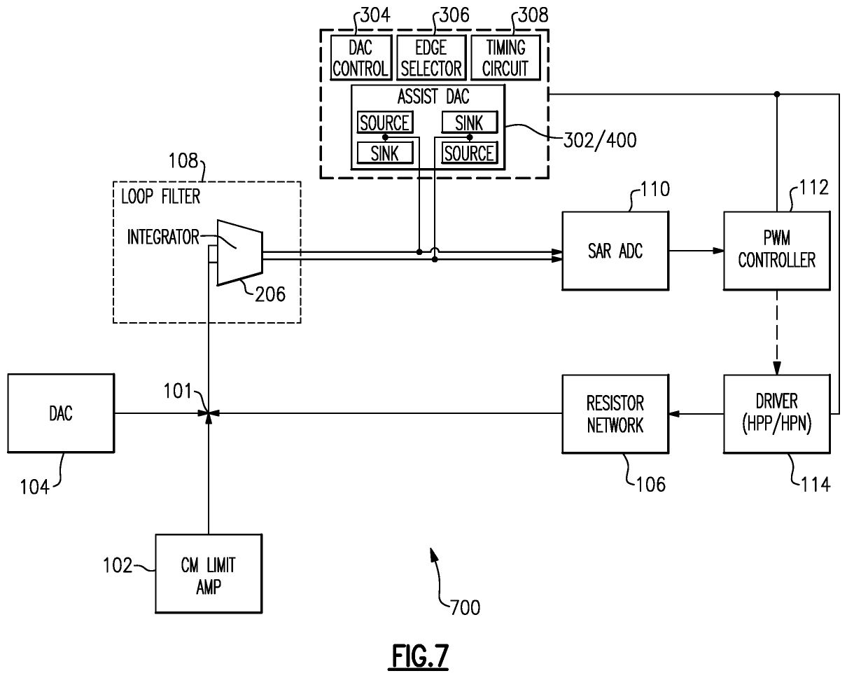

FIG. 7 illustrates one embodiment of a class-D amplifier 700 having an assist DAC configured to provide currents to the outputs of an integrator 206 as described herein. Labels and reference are made to the components of earlier figures such as FIGS. 1, 2, 3 and 4, for the purposes of clarity. The class-D amplifier 700 shows how the various components discussed herein with respect to FIGS. 1-6 can be configured and coupled in one possible context.

FIG. 7 includes a CM limit amplifier 102, DAC 104, resistor network 106, loop filter 108, assist DAC 302, 400, DAC control 304, edge selector 306, timing circuit 308, SAR ADC 110, PWM controller 112, and driver 114.

The CM limit amplifier 102, DAC 104, resistor network 106, and loop filter 108 are coupled together at a summing node 101. The loop filter 108 further includes an integrator 206 having a first differential input and corresponding first differential output, and a second differential input and corresponding second differential output. The differential inputs of the integrator 206 are coupled to the summing node 101, and the differential outputs of the integrator 206 are coupled to the assist DAC 302, 400 and the SAR ADC 110. The SAR ADC 110 is coupled to the PWM controller 112. The PWM controller is coupled to the driver 114 (and in some cases may be only communicatively coupled to the driver 114 rather than physically coupled), and is coupled to the DAC control 304 and/or edge selector 306 and/or timing circuit 308 and/or assist DAC 302, 400. The driver 114 is coupled to the resistor network 106, the PWM controller 112, and to the DAC control 304 and/or edge selector 306 and/or timing circuit 308 and/or assist DAC 302, 400.

As previously described herein, the assist DAC 302, 400, using the sources and sinks it contains (e.g., sources 402a, 404b and sinks 404a, 402b of the pulse DAC 402 and audio DAC 404) may provide currents to the differential outputs of the integrator 206 and/or loop filter 108, such that the currents at each respective differential output equal the currents at the respective differential inputs, that is, the current flowing “in” to a respective differential input is equaled by a current flowing “in” to a corresponding differential output.

Various controllers, such as one or more (alone or in combination) of the DAC control 304, edge selector 306 and/or timing circuit 308, may execute various operations discussed above. Using data stored in associated memory and/or storage, the one or more controllers also executes one or more instructions stored on one or more non-transitory computer-readable media, which the one or more controllers may include and/or be coupled to, that may result in manipulated data. In some examples, the one or more controllers may include one or more processors or other types of controllers. In one example, the controller ______ is or includes at least one processor. In another example, the one or more controllers performs at least a portion of the operations discussed above using an application-specific integrated circuit tailored to perform particular operations in addition to, or in lieu of, a general-purpose processor. As illustrated by these examples, examples in accordance with the present disclosure may perform the operations described herein using many specific combinations of hardware and software and the disclosure is not limited to any particular combination of hardware and software components. Examples of the disclosure may include a computer-program product configured to execute methods, processes, and/or operations discussed above. The computer-program product may be, or include, one or more controllers and/or processors configured to execute instructions to perform methods, processes, and/or operations discussed above.

Having thus described several aspects of at least one embodiment, it is to be appreciated various alterations, modifications, and improvements will readily occur to those skilled in the art. Such alterations, modifications, and improvements are intended to be part of, and within the spirit and scope of, this disclosure. Accordingly, the foregoing description and drawings are by way of example only.

What is claimed is:

1. A system for mitigating error in an amplifier comprising:
a loop filter having a differential output;
a driver coupled to the loop filter and configured to provide a drive signal to the loop filter;
a digital-to-analog converter (DAC) coupled to the differential output and configured to source and sink current on the differential output;
a delay detection circuit configured to determine a drive delay; and
at least one controller configured to
determine an output of the DAC based on the drive signal, and
control the DAC to source or sink current on the differential input based on the drive delay.

2. The system of claim 1 wherein the delay detection circuit includes an edge selector configured to determine the drive delay based on a first time when the driver receives a signal to provide the drive signal and a second time when the driver begins providing the drive signal.

3. The system of claim 1 wherein the delay detection circuit includes a timing circuit configured to determine a DAC delay based on a first time when the DAC receives a signal to source or sink a current and a second time when the DAC begins to source or sink the current.

4. The system of claim 1,
wherein the delay detection circuit is further configured to determine a DAC delay,
wherein the differential output includes a first differential output and a second differential output,
wherein the DAC includes a first source and a first sink coupled to the first differential output, the first source configured to source current on the first differential output, and the first sink configured to sink current on the first differential output, and
the DAC includes a second source and a second sink coupled to the second differential output, the second source configured to source current on the second differential output, and the second sink configured to sink current on the second differential output.

5. The system of claim 1 wherein the driver includes a first driver output connection coupled to the loop filter and a second driver output connection coupled to the loop filter, and the DAC includes a first DAC coupled to the differential output and a second DAC coupled to the differential output.

6. The system of claim 5 wherein the first DAC is configured to provide a first DAC output signal when a first differential voltage is present across the first driver output connection and the second driver output connection, and the second DAC is configured to provide a second DAC output signal when a second differential voltage is present across the first drive output connection and the second driver output connection.

7. The system of claim 6 wherein one of the first differential voltage and the second differential voltage is zero or approximately zero.

8. The system of claim 1 wherein the DAC includes at least one current source configured to shape a DAC current, and to source or sink the DAC current, wherein the DAC current is shaped based on a time-constant of the DAC.

9. A system for mitigating error in an amplifier, the system comprising:
an input;
a control circuit configured to determine a delay between receiving an input signal at the input and providing an output signal at an output; and
an assist digital-to-analog converter (“assist DAC”) configured to source or sink current based on the input signal.

10. The system of claim 9 wherein the delay includes a first delay and a second delay, the first delay being a period of time between a driver receiving a signal to provide the input signal and the driver providing the input signal, and the second delay being a period of time between the assist DAC receiving a signal to source or sink current and the assist DAC sourcing or sinking current.

11. The system of claim 10 wherein the control circuit includes an edge selector configured to determine the first delay and a timing circuit configured to determine the second delay.

12. The system of claim 10 wherein the control circuit controls the assist DAC to source or sink current when the driver is providing the input signal.

13. The system of claim 10 wherein the control circuit controlling the assist DAC to source or sink current when the input signal is present includes the control circuit accounting for the first delay and the second delay, wherein accounting for the first delay and the second delay includes minimizing an amount of time the assist DAC sources or sinks current during which the driver is not providing the input signal.

14. The system of claim 9 wherein the assist DAC includes a plurality of DACs, each DAC of the plurality of DACs having a respective source and a respective sink.

15. The system of claim 9 further comprising an integrator coupled between the input and the output.

16. A method of minimizing feedback error in an amplifier comprising:
providing a driver control signal to a driver, the driver control signal instructing the driver to provide a driver output;
providing the driver output from the driver responsive to receiving the driver control signal;
determining a delay between providing the driver control signal to the driver and the driver providing the driver output;
determining a polarity of the driver output;
sourcing a first current responsive to determining that the polarity is positive; and
sinking a second current responsive to determining that the polarity is negative.

17. The method of claim 16 further comprising:
sourcing the first current or sinking the second current based on the delay.

18. The method of claim 17 wherein sourcing the first current or sinking the second current based on the delay includes sourcing or sinking a current by using the delay to determine when the driver will begin providing the driver output, and timing sourcing or sinking the current to correspond to when the driver begins providing the driver output.

19. The method of claim 16 further comprising:
determining a source delay or a sink delay, wherein the source delay is a first amount of time between providing a source control signal and sourcing the first current, and the sink delay is a second amount of time between providing a sink control signal and sinking the second current.

20. The method of claim 19 wherein sourcing the first current based on the delay includes sourcing the first current based on the source delay by using the source delay to determine when the first current will begin to be sourced and timing the first current to begin to be sourced to correspond to when the driver begins to provide the driver output, and
wherein sinking the second current based on the delay sinking the second current based on the sink delay by using the sink delay to determine when the second current will being to be sinked and timing the second current to begin to be sinked to correspond to when the driver begins to provide the driver output.
